(19) United States
(12) Patent Application Publication
(10) Pub. No.: US 2025/0038083 A1
(43) Pub. Date: Jan. 30, 2025

(54) SEMICONDUCTOR DEVICE

(71) Applicant: SAMSUNG ELECTRONICS CO., LTD., Suwon-si (KR)

(72) Inventors: Junho LEE, Suwon-si (KR); Insik HAN, Suwon-si (KR)

(21) Appl. No.: 18/438,719

(22) Filed: Feb. 12, 2024

(30) Foreign Application Priority Data
Jul. 27, 2023 (KR) 10-2023-0098320

(51) Int. Cl. H01L 23/498

(52) U.S. Cl. CPC H01L 23/49816; H01L 23/49883

(57) ABSTRACT

A semiconductor device according to embodiments includes a semiconductor package, a package pad positioned on a surface of the semiconductor package, and a solder ball positioned on the package pad. The package pad includes a package center pad positioned at the center of the semiconductor package, and a package edge pad positioned on an edge portion of the semiconductor package, the package edge pad covers a side surface extending from a surface of the semiconductor package.

### CROSS-REFERENCE TO RELATED APPLICATION

This application claims priority under 35 U.S.C. § 119 to Korean Patent Application No. 10-2023-0098320 filed in the Korean Intellectual Property Office on Jul. 27, 2023, and all the benefits accruing therefrom, the entire contents of which are incorporated herein by reference.

### BACKGROUND

### (a) Field of the Invention

The present disclosure relates to a semiconductor device.

### (b) Description of the Related Art

As the size of semiconductor chips is gradually reduced, surface mounting technology (SMT), which facilitates mass production and higher integration, is used in a mounting process. The SMT is a method of soldering by bringing a pad of a semiconductor chip into contact with a pad of a substrate. The method involves applying a paste to the mounting substrate, placing the package on the mounting substrate aligned with the pad, applying heat in a reflow process that melts the paste, and the reflowed paste is allowed to cool and harden.

A surface mount package can have terminals on the lower surface. The surface mount package may include a land grid array (LGA) package in which a metal surface is located on the lower surface of the package substrate, and a ball grid array (BGA) package in which solder balls are disposed on the lower surface of the package substrate.

### SUMMARY

For ecological reasons and cost reduction purposes, a reflow process may be performed at a temperature of less than 200° C. using a paste having a lower melting point than that of solder balls. In this case, the solder ball does not melt, and the collapsing height of the semiconductor package in the board direction may be reduced. Accordingly, the occurrence of non-wetting of the electrical contacts may be increased.

Embodiments of the present disclosure may increase the collapsing height of a semiconductor package and reduce non-wetting in a reflow process performed at a temperature of less than 200° C.

A semiconductor device according to embodiments includes a semiconductor package, a package center pad positioned at the center of the semiconductor package, a package edge pad positioned on an edge portion of the semiconductor package, wherein the package edge pad covers at least a portion of a side surface of the semiconductor package, and a solder ball positioned on the package center pad.

A semiconductor device according to embodiments includes a semiconductor package, a package pad positioned on a surface of the semiconductor package, and a solder ball positioned on the package pad. The package pad includes a package center pad positioned at the center of the semiconductor package, and a package edge pad positioned on an edge portion of the semiconductor package, wherein the package edge pad is thicker than the package center pad.

A semiconductor device according to embodiments includes a semiconductor package, a package pad on a surface of the semiconductor package, a board facing the semiconductor package, a board pad on a surface of the board, a paste on the board pad, and a solder ball between the package pad and the paste, wherein the package pad includes a package center pad positioned in the center of the semiconductor package, and a package edge pad positioned on an edge portion of the semiconductor package, and wherein the board pad includes a board center pad facing the package center pad, and a board edge pad facing the package edge pad, wherein the solder ball is positioned between the package center pad and the board center pad, and a surface of the package edge pad faces the board and a side surface extending from the surface are covered with the paste.

According to embodiments, it is possible to provide a semiconductor device capable of increasing the collapsing height of a semiconductor package and reducing non-wetting in a reflow process performed at a temperature of less than 200° C.

### BRIEF DESCRIPTION OF THE DRAWINGS

FIG. 1 is a cross-sectional view of a semiconductor device in which a semiconductor package and a board are aligned with each other, according to an embodiment.

FIG. 2 is an enlarged cross-sectional view of region A of FIG. 1.

FIG. 3 is a cross-sectional view of a semiconductor device in which a semiconductor package is mounted on a board, according to an embodiment.

FIG. 4 is an enlarged view of region B of FIG. 3.

FIG. 5 is a diagram comparing collapsing heights of a semiconductor device with a reference, according to an embodiment.

FIG. 6 is a schematic perspective view of a semiconductor package, according to an embodiment.

FIG. 7 is a schematic top view of a semiconductor package, according to an embodiment.

FIGS. 8 and 9 are schematic vertical cross-sectional views of a semiconductor package, according to an embodiment.

FIG. 10 is a schematic perspective view of a semiconductor package, according to an embodiment.

FIG. 11 is a schematic top view of a semiconductor package, according to an embodiment.

FIG. 12 is a schematic, perspective view of a semiconductor package, according to an embodiment.

FIG. 13 is a schematic top view of a semiconductor package, according to an embodiment.

FIG. 14 is a schematic top view of a package substrate on which a plurality of semiconductor chips are packaged before singulation, according to an embodiment.

FIG. 15 is a schematic perspective view illustrating a plurality of semiconductor packages after singulation, according to an embodiment.

### DETAILED DESCRIPTION OF THE EMBODIMENTS

Hereinafter, the embodiments of the present disclosure will be described in detail with reference to the accompanying drawings. As those skilled in the art would realize, the described embodiments may be modified in various different ways without departing from the spirit or scope of the disclosure and claims.

The drawings and description are to be regarded as illustrative in nature and not restrictive. Like reference numerals designate like elements throughout the specification.

The size and thickness of the various constituent elements in the drawings are arbitrarily illustrated for better understanding and ease of description, but the following embodiments are not limited thereto. In the drawings, the thickness of layers, films, panels, regions, etc., may be exaggerated for clarity. The thickness of some layers and regions may be exaggerated for ease of description.

It will be understood that when an element such as a layer, film, region, or substrate is referred to as being “on” or “above” another element, it can be directly on the other element or intervening elements may also be present. In contrast, when an element is referred to as being “directly on” another element, there are no intervening elements present. Furthermore, when an element is referred to as being “on” or “above” a reference element, it can be positioned above or below the reference element, and it is not necessarily referred to as being positioned “on” or “above” in a direction opposite to gravity.

In addition, unless explicitly described to the contrary, the word “comprise”, and variations such as “comprises” or “comprising”, will be understood to imply the inclusion of stated elements but not the exclusion of any other elements.

Furthermore, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, a semiconductor device according to embodiments will be described with reference to drawings.

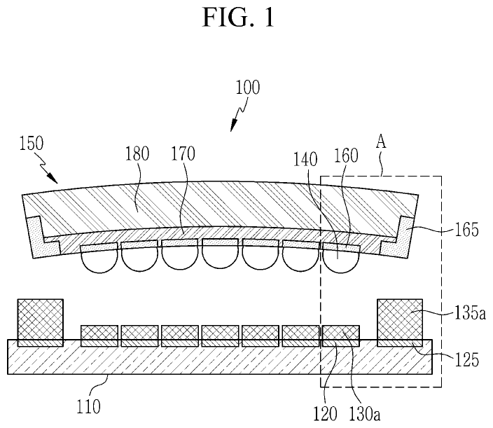

FIG. 1 is a cross-sectional view of a semiconductor device 100 in which a semiconductor package 150 and a board 110 are aligned with each other, according to an embodiment.

Referring to FIG. 1, the semiconductor device 100 may include the semiconductor package 150 and the board 110. One or more components are adjacent to a solder ball 140 in the semiconductor package 150 and one or more components are adjacent to pastes 130a and 135a in the board 110. Some components of the semiconductor package 150 and the board 110 may be omitted for clarity.

According to various embodiments, the semiconductor device 100 may include the semiconductor package 150, package pads 160 and 165, the board 110, board pads 120 and 125, the pastes 130a and 135a, and the solder balls 140. The semiconductor package 150 may include a package substrate 170 to which a semiconductor chip can be bonded, and a sealing member 180.

In the semiconductor package 150, a warpage may occur due to contraction after heat treatment during a packaging process caused by a difference in thermal expansion coefficients between the components. As shown in FIG. 1, the semiconductor package 150 may be bent in an upwardly convex shape, where the semiconductor package 150 bows away from the board 110, but is not limited thereto, and may be bent in a downwardly convex shape. If the collapsing height of the semiconductor package 150 toward the board 110 decreases when the semiconductor package 150 is mounted on the board 110, non-wetting may occur on some solder balls 140 that are farther from the board 110 due to the warpage of the semiconductor package 150, where the central solder balls 140 can be farther from the board pads 120 in the upwardly convex shape.

In various embodiments, the package substrate 170 is a substrate electrically connecting the semiconductor chip and the board 110, enabling transmitting and receiving electrical signals between the semiconductor chip and the board 110.

In various embodiments, the sealing member 180 may seal the semiconductor chip to the package substrate 170. The sealing member 180 may include a molding compound, molding underfill, epoxy, and/or resin, and may be, for example, an epoxy molding compound (EMC).

In various embodiments, the package pads 160 and 165 may be positioned on a surface of the semiconductor package 150. The package pads 160 and 165 may include a package center pad 160 positioned at the center of the semiconductor package 150, and a package edge pad 165 positioned on the edge portion of the semiconductor package 150.

In various embodiments, the surface of the semiconductor package 150 on which the package pads 160 and 165 are positioned may be a surface of the package substrate 170 facing the board 110. The package center pad 160 may be positioned at the center of the package substrate 170 between the package edge pads 165.

The package edge pad 165 may be positioned at an edge portion of the package substrate 170.

In various embodiments, the package center pads 160 may be arranged in various patterns, where for example, the package center pads 160 may be arranged in a lattice shape. The package edge pad 165 may surround the package center pads 160.

In various embodiments, the package edge pad(s) 165 may cover a side surface extending from a surface of the semiconductor package 150, where the package edge pad(s) 165 may cover a side surface of the package substrate 170. As an example shown in FIG. 1, the package edge pad 165 may have an L-shape on a vertical cross-section of the semiconductor package 150, where the package edge pad 165 may wrap around a corner of the semiconductor package 150. In various embodiments, the package edge pad 165 may have a quadrangle shape on a vertical cross-section of the semiconductor package 150, and form a lower corner of the semiconductor package 150.

In various embodiments, the package center pads 160 and package edge pad(s) 165 may each include a metal layer. For example, the package pads 160 and 165 may include at least one layer of copper, aluminum, tungsten, nickel, gold, tin, titanium, or alloys thereof.

In various embodiments, the package center pad(s) 160 may be electrically connected to the package substrate 170 and the semiconductor chip. The package edge pad(s) 165 may be electrically floating. Electricity may be applied to the package center pad(s) 160, but not applied to the package edge pad(s) 165. Accordingly, the package edge pad(s) 165 may not affect electrical characteristics and reliability of the semiconductor package 150 or the semiconductor device 100.

In various embodiments, the board 110 is a printed circuit board on which the semiconductor package 150 is mounted, and may be, for example, a main board or a mother board. The board 110 faces the semiconductor package 150. Board pads 120 and 125 may be positioned on a surface of the board 110, where the board pads may be facing the semiconductor package 150.

In various embodiments, the board pads 120 and 125 may include the board center pad 120, which may be aligned with and facing the package center pad 160, and the board edge pad 125, which may be aligned with and facing the package edge pad 165. The board center pads 120 may be arranged in the same pattern as the package center pads 160. For example, when the package center pads 160 are arranged in a lattice pattern, the board center pads 120 may also be arranged in a lattice pattern.

In various embodiments, the pastes 130a and 135a can affix the semiconductor package 150 to the board 110, and may include, for example, a solder paste in which alloy particles and a flux are mixed. In various embodiments, the pastes 130a and 135a may be low-temperature solder pastes having a reflow peak temperature of 170° C. or higher and less than 200° C. The semiconductor package 150 can adhere to the board 110 through physical connections made through the board pads 120, 125, pastes 130a, 135a, solder balls 140, and package pad 160, 165.

In various embodiments, the reflow peak temperature of the pastes 130a and 135a may be about 190° C. to about 200° C. When a low-temperature solder paste is used, the reflow process is performed at a relatively low temperature, so CO₂ emission and process cost may be reduced compared to a reflow process performed at a high temperature of greater than 200° C. In embodiments, the pastes 130a and 135a may be SnBi-based low-temperature solder pastes that begin to melt at about 138° C. The pastes 130a and 135a may be in a state before melting before a reflow process.

In various embodiments, the pastes 130a and 135a may be placed on the board pad 120 and 125, where the pastes 130a and 135a may be divided into a center paste 130a positioned on the board center pad(s) 120 and an edge paste 135a positioned on the board edge pad(s) 125. The amount of the edge paste 135a placed on the board edge pad(s) 125 may be greater than the amount of the center paste 130a placed on a board center pad 120.

In various embodiments, the solder ball 140 is a ball-shaped component for physically and electrically connecting the semiconductor package 150 to the board 110, and may be attached to a surface of the package substrate 170 facing the board 110. In embodiments, the solder ball 140 may be a SAC (Sn, Ag, and Cu) based solder ball made of an alloy including tin (Sn), silver (Ag), and copper (Cu).

In various embodiments, the solder ball 140 may be positioned on the package pads 160 and 165, where the solder ball 140 may be positioned between the package pad 160 and 165 and the pastes 130a and 135a. The solder balls 140 may be positioned between the package center pads 160 and the center paste 130a positioned on the board center pads 120. In various embodiments, the solder ball 140 may not be positioned between the package edge pad 165 and the edge paste 135a. At least a portion of the surface of the package center pad 160 facing the board 110 may be covered by the solder ball 140.

When the semiconductor package 150 and the board 110 get closer, the center paste 130a positioned on the board center pad(s) 120 may contact the solder ball 140, and the edge paste 135a positioned on the board edge pad(s) may 125 contact the package edge pad 165.

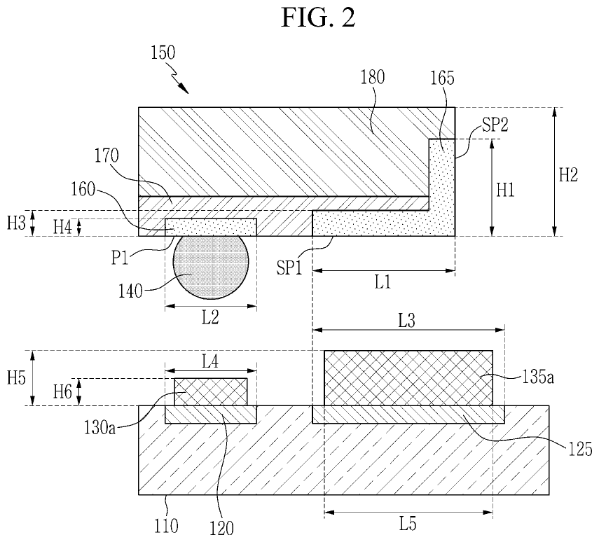

FIG. 2 is a cross-sectional view of the semiconductor device 100 according to embodiments in which the semiconductor package 150 and the board 110 are aligned before a reflow process. FIG. 2 is an enlarged view of region A of FIG. 1. Although the semiconductor package 150 is illustrated as being bent in FIG. 1, the semiconductor package 150 is illustrated in an unbent state for convenience in FIG. 2. For convenience, the components adjacent to the solder ball 140 in the semiconductor package 150 and components adjacent to the pastes 130a and 135a in the board 110 are shown, and some components of the semiconductor package 150 and the board 110 are omitted for clarity.

Referring to FIG. 2, the semiconductor device 100 may include the semiconductor package 150, the package center pad 160, the package edge pad 165, the board 110, the board center pad 120, the board edge pad 125, the center paste 130a positioned on the board center pad 120, the edge paste 135a positioned on the board edge pad 125, and the solder ball 140.

In various embodiments, the semiconductor package 150 may include the package substrate 170 to which a semiconductor chip is bonded and the sealing member 180. The sealing member 180 may cover a surface of the package substrate 170 to which the semiconductor chip is bonded.

In various embodiments, the package center pad(s) 160 may be disposed on a surface of the semiconductor package 150 facing the board 110. The package edge pad 165 may cover a surface of the semiconductor package 150 facing the board 110 and a side surface of the semiconductor package 150 extending therefrom.

In various embodiments, the board center pad(s) 120 and the board edge pad(s) 125 may cover a surface of the board 110 facing the semiconductor package 150. The board center pad(s) 120 may be positioned to face the package center pad(s) 160, where the board center pad(s) 120 may be aligned with the package center pad(s) 160. For example, the center of the package center pad 160 and the center of the board center pad 120 may exist on the same vertical line (e.g., be colinear). The board edge pad(s) 125 may be positioned to face the package edge pad(s) 165. For example, a point of the package edge pad 165 closest to the center of the semiconductor package 150 and a point of the board edge pad 125 closest to the center of the board 110 may be on the same vertical line.

In various embodiments, the pastes 130a and 135a may be positioned on the board pad 120 and 125. The center paste 130a positioned on the board center pads 120 may face the solder balls 140, and the edge paste 135a positioned on the board edge pads 125 may face the package edge pads 165.

In various embodiments, the solder ball 140 may cover at least a portion of the surface P1 of the package center pad 160 on which the solder ball 140 is located. The solder ball 140 may be positioned between the package center pad 160 and the center paste 130a positioned on the board center pad 120.

A thickness H3 of the package edge pad 165 may be greater than a thickness H4 of the package center pad 160. In various embodiments, the package edge pad 165 may have an L-shape on a vertical cross-section of the semiconductor package 150. In this case, the thickness H3 of the portion adjacent to the package center pad 160 of the package edge pad 165 and the thickness H1 of the portion adjacent to the side surface of the semiconductor package 150 of the package edge pad 165 may be different. The thickness H1 of the portion adjacent to the side surface of the semiconductor package 150 of the package edge pad 165 may be thicker than the thickness H3 of the portion adjacent to the package center pad 160 of the package edge pad 165, and the thickness H3 of the portion adjacent to the package center pad 160 of the package edge pad 165 may be thicker than the thickness H4 of the package center pad 160.

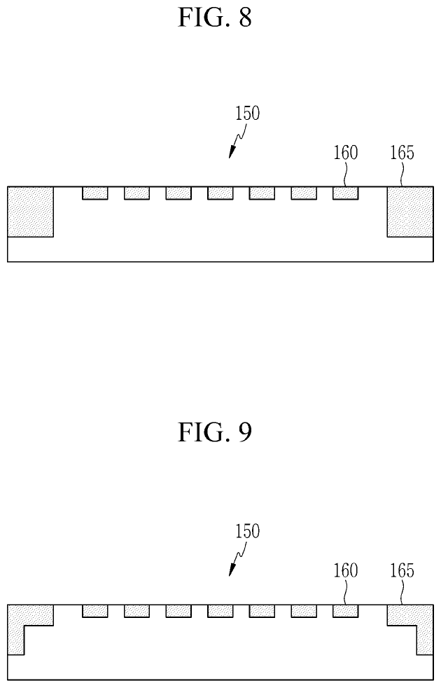

In an embodiment, as illustrated in FIG. 8, the package edge pad 165 may have a quadrangle shape on a vertical cross-section of the semiconductor package 150. In this case, the thickness H3 of the portion adjacent to the package center pad 160 of the package edge pad 165 and the thickness H1 of the portion adjacent to the side surface of the semiconductor package 150 of the package edge pad 165 may be the same. A thickness (H1=H3) of the package edge pad 165 may be greater than a thickness H4 of the package center pad 160.

In various embodiments, the thickness H1 of the package edge pad 165 on the side surface of the semiconductor package 150 may be greater than or equal to about 10% and less than 100% of the thickness H2 of the semiconductor package 150. A surface of the semiconductor package 150 on which the package pads 160 and 165 are positioned may be a surface of the semiconductor package 150 facing the board 110. The thickness H2 of the semiconductor package 150 measured from a surface of the semiconductor package 150, where the package pad 160 and 165 are positioned, may be a height of the semiconductor package 150 excluding the solder ball 140. For example, when the thickness H1 of the package edge pad 165 is less than about 10% of the thickness H2 of the semiconductor package 150, the area where the edge paste 135a contacts a surface SP2 of the package edge pad 165 may be reduced, thereby reducing the height at which the semiconductor package 150 collapses toward the board 110.

In various embodiments, a length L1 of the package edge pad 165 may be equal to a length L2 of the package center pad 160 or longer than the length L2 of the package center pad 160. The length L1 of the package edge pad 165 may be greater than or equal to 100% of the length L2, and less than about 300% of the length L2 of the package center pad 160. For example, when the length L1 of the package edge pad 165 is less than 100% of the length L2 of the package center pad 160, the area where the edge paste 135a contacts the surface SP1 of the package edge pad 165 that covers a surface of the semiconductor package 150 facing the board 110 during the reflow process may be reduced, thereby reducing the length at which the semiconductor package 150 collapses toward the board 110. When the length L1 of the package edge pad 165 is 300% or more of the length L2 of the package center pad 160, a short circuit with the center paste 130a covering the solder ball 140 adjacent to the package edge pad 165 may occur during the reflow process.

In various embodiments, the amount of the edge paste 135a on the board edge pad 125 may be greater than the amount of the center paste 130a on the board center pad 120. In various embodiments, a height H5 of the edge paste 135a positioned on the board edge pad 125 may be greater than or equal to 100% of a height H6, and less than about 200% of a height H6 of the center paste 130a positioned on the board center pad 120. When the height H5 of the edge paste 135a positioned on the board edge pad 125 is less than 100% of the height H6 of the center paste 130a positioned on the board center pad 120, the center paste 130a may not contact the package edge pad 165, which is farther from the surface of the solder ball 140, based on the plane of the board 110. When the height H5 of the edge paste 135a positioned on the board edge pad 125 is greater than or equal to about 200% of the height H6 of the center paste 130a positioned on the board center pad 120, the amount of the edge paste 135a may be excessive, which may cause a short circuit with the adjacent solder ball 140 and/or the center paste 130a.

In various embodiments, a length L3 of the board edge pad 125 may be longer than a length L4 of the board center pad 120. A greater amount of paste may be on the board edge pad 125 than on the board center pad 120.

In various embodiments, the length L3 of the board edge pad 125 may be longer than the length L1 of the package edge pad 165. The length L3 of the board edge pad 125 may be greater than or equal to about 120% and less than about 200% of the length L1 of the package edge pad 165. For example, when the length L3 of the board edge pad 125 is less than about 120% of the length L1 of the package edge pad 165, the area where the edge paste 135a positioned on the board edge pad 125 contacts the surface SP2 of the package edge pad 165 that covers a side surface of the semiconductor package 150 may be reduced, thereby reducing the height at which the semiconductor package 150 collapses toward the board 110. When the length L3 of the board edge pad 125 is greater than or equal to about 200% of the length L1 of the package edge pad 165, the board edge pad 125 and/or the edge paste 135a positioned on the board edge pad 125 may be shorted with adjacent terminals on the board 110.

In various embodiments, a length L5 of the edge paste 135a positioned on the board edge pad 125 may be greater than or equal to about 70% and less than about 130% of the length L3 of the board edge pad 125. When the length L5 of the edge paste 135a positioned on the board edge pad 125 is less than about 70% of the length L3 of the board edge pad 125, the area where the edge paste 135a positioned on the board edge pad 125 contacts the package edge pad 165 during the reflow process may be reduced, thereby reducing the height at which the semiconductor package 150 collapses toward the board 110. When the length L5 of the edge paste 135a positioned on the board edge pad 125 is greater than or equal to about 130% of the length L3 of the board edge pad 125, the amount of the edge paste 135a may be excessive, which may cause a short circuit with the adjacent solder ball 140 and/or the center paste 130a.

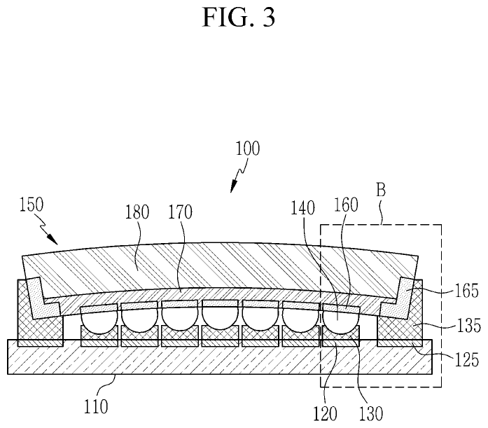

FIG. 3 is a cross-sectional view of the semiconductor device 100 according to embodiments in which the semiconductor package 150 is mounted on the board 110 after a reflow process. FIG. 3 is a diagram illustrating the semiconductor device 100 after a reflow process is performed on the semiconductor device 100 of FIG. 1. For convenience, the components adjacent to the solder ball 140 in the semiconductor package 150 and components adjacent to the pastes 130a and 135a in the board 110 are shown, and some components of the semiconductor package 150 and the board 110 are omitted.

Because the description of the same configuration as that of FIG. 1 can be applied to FIG. 3, duplicate descriptions may be omitted. Hereinafter, differences from FIG. 1 will be mainly described with reference to FIG. 3.

Referring to FIG. 3, the pastes 130a and 135a of FIG. 1 may be melted by the reflow process, and the melted pastes 130a and 135a may be cooled and hardened while covering the surfaces of the solder ball 140 and the package edge pad 165.

The melted center paste 130 positioned on the board center pad 120 may be hardened while covering the solder ball 140. The melted edge paste 135 positioned on the board edge pad 125 may be hardened while covering the package edge pad 165.

In various embodiments, the reflow peak temperatures of the pastes 130a and 135a of FIG. 1 may be greater than or equal to about 170° C. and less than about 200° C. The reflow peak temperatures of the pastes 130a and 135a of FIG. 1 may be preferably greater than or equal to about 190° C. and less than about 200° C. For example, the pastes 130a and 135a of FIG. 1 may be SnBi-based low-temperature solder pastes. For example, the reflow process may be performed at a temperature of greater than or equal to about 138° C. and less than about 200° C., which is the melting point of SnBi-based low-temperature solder paste.

In various embodiments, the solder ball 140 may have a melting point of greater than or equal to 200° C. For example, the solder ball 140 may be a SAC based solder ball, such that the solder ball 140 may not melt during a reflow process.

After the reflow process, at least a portion of the solder ball 140 may be covered by the center paste 130. At least a portion of the surface of the package center pad 160 facing the board 110 may be covered by the solder ball 140. Because the package center pad 160 is connected to the package substrate 170 and a circuit of a semiconductor chip bonded to the package substrate 170, the package center pad 160 may be connected to the board 110 through the solder ball 140 and the center paste 130, thereby transferring an electrical signal between the semiconductor package 150 and the board 110.

After the reflow process, the package edge pad 165 may be covered by the edge paste 135. Because the package edge pad 165 may be electrically floated, electrical signal transmission between the semiconductor package 150 and the board 110 may not be affected even though the package edge pad 165 is connected to the board 110 through the center paste 130.

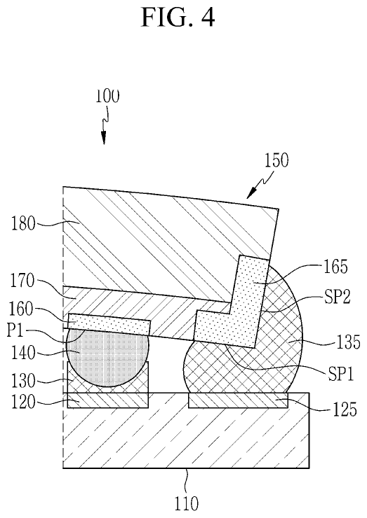

FIG. 4 is a cross-sectional view of the semiconductor device 100 according to embodiments in which the semiconductor package 150 is mounted on the board 110 after a reflow process. FIG. 4 is an enlarged view of region B of FIG. 3. For convenience, the components adjacent to the solder ball 140 in the semiconductor package 150 and components adjacent to the pastes 130 and 135 in the board 110 are shown, and some components of the semiconductor package 150 and the board 110 are omitted. Among the components of FIG. 4, redundant descriptions of components that are the same as those of FIG. 2 may be omitted. Hereinafter, differences from FIG. 2 will be mainly described with reference to FIG. 4.

Referring to FIG. 4, the semiconductor device 100 may include the semiconductor package 150, the package center pad 160, the package edge pad 165, the board 110, the board center pad 120, the board edge pad 125, the center paste 130 on the board center pad 120, the edge paste 135 on the board edge pad 125, and the solder ball 140. The semiconductor package 150 may include the package substrate 170 to which a semiconductor chip is bonded and the sealing member 180.

In various embodiments, at least a portion of the surface P1 of the package center pad 160 facing the board 110 may be covered by the solder ball 140. When heat treatment is performed at the reflow peak temperature of the pastes 130 and 135, the center paste 130 positioned on the board center pad 120 melts and may be deformed into a near-spherical shape by surface tension. The center paste 130 may flow along the surface of the solder ball 140 to cover at least a portion of the solder ball 140, and then hardened while covering the solder ball 140, as the center paste 130 cools down. After the reflow process, the center paste 130 positioned on the board center pad 120 may cover at least a portion of the solder ball 140.

In various embodiments, the surface SP1 of the package edge pad 165 facing the board 110 and the surface SP2 covering the side surface of the semiconductor package 150 may be exposed to the outside. When a heat treatment is performed at the reflow peak temperature of the pastes 130 and 135, the edge paste 135 positioned on the board edge pad 125 melts and may be deformed into a near-spherical shape by surface tension. The edge paste 135 may flow along a surface SP1 of the package edge pad 165 facing the board 110 and the side surface of the semiconductor package 150 to cover at least a portion of the package edge pad 165, and then hardened while covering the package edge pad 165, as the edge paste 135 cools down. After the reflow process, the edge paste 135 positioned on the board edge pad 125 may cover at least a portion of the surface SP1 of the package edge pad 165 facing the board 110 and the surface SP2 covering the side surface of the semiconductor package 150.

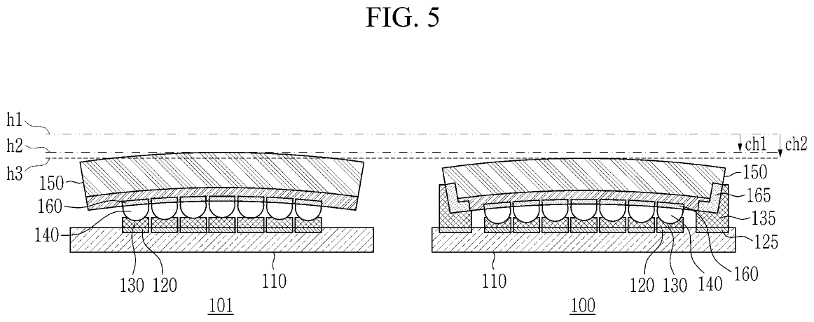

FIG. 5 is a diagram comparing collapsing heights of the semiconductor device 100 according to various embodiments and a semiconductor device 101 according to a comparative example by a reflow process. The semiconductor device 100 of FIG. 5 may be the semiconductor device 100 described above with reference to FIGS. 1 to 4.

The semiconductor device 101 according to the comparative example may include the semiconductor package 150, the package center pad 160 positioned on a surface of the semiconductor package 150, the board 110 facing the semiconductor package 150, the board center pads 120 positioned on a surface of the board 110, the center paste 130 positioned on the board center pads 120, and the solder ball 140 positioned between the package center pads 160 and the center paste 130. The package center pads 160 of the semiconductor device 101 may be positioned in the center of the semiconductor package 150. The board center pads 120 may face the package center pads 160.

By the reflow process, the center paste 130 of the semiconductor device 101 may cover at least a portion of the solder ball 140. As the center paste 130 and the solder ball 140 are bonded, the semiconductor package 150 and the board 110 of the semiconductor device 101 may get close to each other. When the semiconductor package 150 gets closer to the board 110, the semiconductor device 101 may be said to “collapse.”

The semiconductor device 100 according to various embodiments may include the semiconductor package 150, the package pads 160 and 165 positioned on a surface of the semiconductor package 150, the board 110 facing the semiconductor package 150, the board pads 120 and 125 positioned on a surface of the board, the center paste 130 positioned on the board pads 120 and 125, and the solder ball 140 positioned between the package center pads 160 and the center paste 130. The package pads 160 and 165 of the semiconductor device 101 may include the package center pads 160 positioned in the center of the semiconductor package and the package edge pads 165 positioned at the edge portion of the semiconductor package. The board pads 120 and 125 may include the board center pads 120 facing the package center pads 160 and the board edge pads 125 facing the package edge pads 165.

By the reflow process, the center paste 130 positioned on the board center pads 120 of the semiconductor device 100 may cover at least a portion of the solder ball. By the reflow process, the edge paste 135 positioned on the board edge pads 125 of the semiconductor device 100 may cover at least a portion of the package edge pad 165. The edge paste 135 may cover at least a portion of the surface of the package edge pads 165 facing the board 110 and a side surface extending from a surface facing the board 110. As the pastes 130 and 135 are bonded to the solder ball 140 and the package edge pad 165, the semiconductor package 150 and the board 110 of the semiconductor device 100 may get close to each other. When the semiconductor package 150 gets closer to the board 110, the semiconductor device 100 may be said to “collapse.”

In various embodiments, the semiconductor device 100 according to embodiments may further include the package edge pad 165, the board edge pad 125, and the edge paste 135 disposed on the board edge pad 125 in the configurations of the semiconductor device 101 of the comparative example. As the edge paste 135 is bonded to the package edge pad 165, a collapsing height of the semiconductor device 100 may be greater than a collapsing height of the semiconductor device 101 according to the comparative example.

The height h1 may be a height of the semiconductor device 100 according to various embodiments, as shown in FIG. 5, and the semiconductor device 101 may be in a state in which the semiconductor package 150 is aligned on the board 110 before the reflow process. Before the reflow process, the heights of the semiconductor device 100 and the semiconductor device 101 may be the same.

The height h2 may be the height of the semiconductor device 101 after heat treatment and the reflow process are completed. A collapsing height ch1 of the semiconductor device 101 by the reflow process may be represented as h1-h2.

The height h3 may be the height of the semiconductor device 100 after the heat treatment and the reflow process are completed. A collapsing height ch2 of the semiconductor device 100 may be represented as h1-h3.

The collapsing height ch2 of the semiconductor device 100 may be greater than the collapsing height ch1 of the semiconductor device 101 of the comparative example. The greater the collapsing height, the smaller the distance between the semiconductor package 150 and the board 110. The greater the distance between the semiconductor package 150 and the board 110, the greater the probability of non-wetting of some of the solder balls 140 of the semiconductor device 100.

The semiconductor device 100, according to various embodiments, has a greater collapsing height than the semiconductor device 101, according to the comparative example. Accordingly, non-wetting of the solder ball 140 may be reduced.

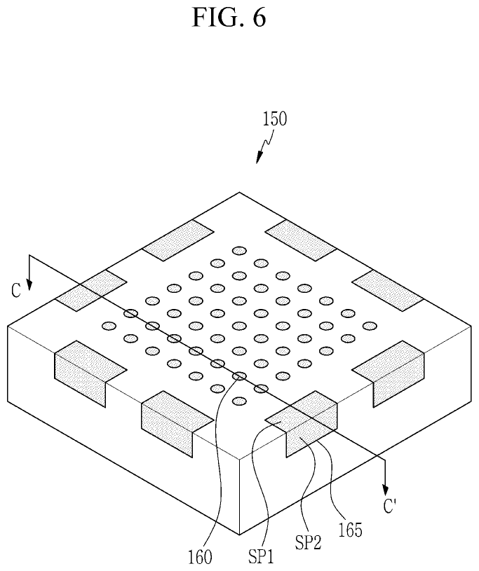

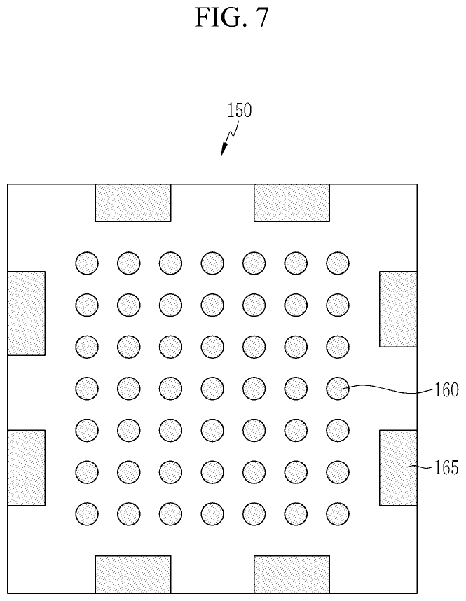

FIG. 6 is a schematic perspective view of the semiconductor package 150 according to various embodiments. FIG. 7 is a schematic top plan view of the semiconductor package 150 according to various embodiments. In FIGS. 6 and 7, the package pad 160 and 165 of the semiconductor package 150 are shown, and other components are omitted. The semiconductor package 150 of FIGS. 6 and 7 may be the semiconductor package 150 included in the semiconductor device 100 of FIGS. 1 to 5. FIG. 6 is a perspective view of a surface of the semiconductor package 150 facing the board 110 viewed from above. FIG. 7 is a top view of the surface of the semiconductor package 150 of FIG. 6 facing the board 110 viewed from above. A surface of the semiconductor package 150 facing the board 110 may be the surface of the package substrate 170. The semiconductor package 150 of FIGS. 6 and 7 may be in a state before the solder ball 140 is mounted.

Referring to FIGS. 6 and 7, a surface of the semiconductor package 150 facing the board 110 may include the package center pads 160 and the package edge pads 165.

In various embodiments, the package center pads 160 may be positioned in the center of the semiconductor package 150, where the package center pads 160 may be arranged in various patterns, for example, the package center pads 160 may be arranged in an array or lattice pattern. The number of package center pads 160 is not limited to the number shown in FIGS. 6 and 7. Solder balls 140 may be mounted on each of the plurality of package center pads 160.

In various embodiments, the package edge pads 165 may be positioned on an edge portion of the semiconductor package 150. The package edge pads 165 may be disposed to surround the package center pad 160. The package edge pads 165 may cover at least a portion of the surface of the semiconductor package 150 facing the board 110 and a side surface extending therefrom. The package edge pads 165 may have the surface SP1 facing the board 110 and a side surface SP2 extending from the surface SP1 facing the board 110.

In various embodiments, the plurality of package edge pads 165 may be spaced apart from each other along the edge of the semiconductor package 150. In various embodiments, the plurality of package edge pads 165 may have a quadrangle shape. The number of the plurality of package edge pads 165 is not limited to the number shown in FIGS. 6 and 7.

FIGS. 8 and 9 are schematic vertical cross-sectional views of the semiconductor package 150 in various embodiments. FIGS. 8 and 9 may be cross-sectional views taken along C-C′ line of FIG. 6. In FIGS. 8 and 9, the package pads 160 and 165 of the semiconductor package 150 are shown, and other components are omitted.

Referring to FIG. 8, the package edge pad 165 may have a quadrangle shape on a vertical cross-section of the semiconductor package 150. The package edge pad 165 may be thicker than the package center pad 160. In the embodiment, as shown in FIG. 8, the package edge pads 165 may have a constant thickness.

Referring to FIG. 9, the shape of the package edge pads 165 on the vertical cross-section of the semiconductor package 150 may be L-shaped. In the embodiment shown in FIG. 9, the thickness of the portion of the package edge pad 165 adjacent to the side surface of the semiconductor package 150 may be thicker than the thickness of the portion of the package edge pad 165 adjacent to the package center pad 160. A thickness of a portion of the package edge pad 165 adjacent to the package center pad 160 may be thicker than that of the package center pad 160.

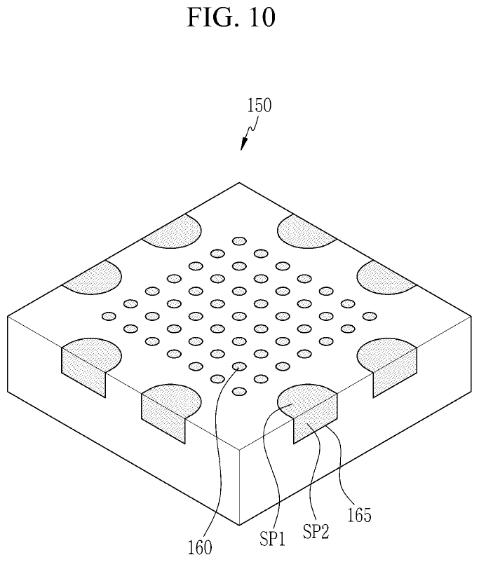

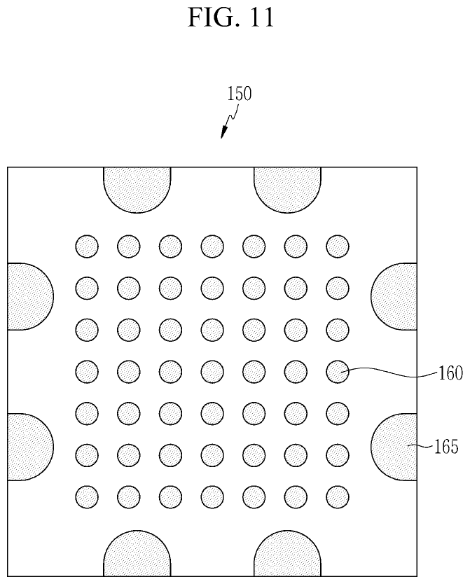

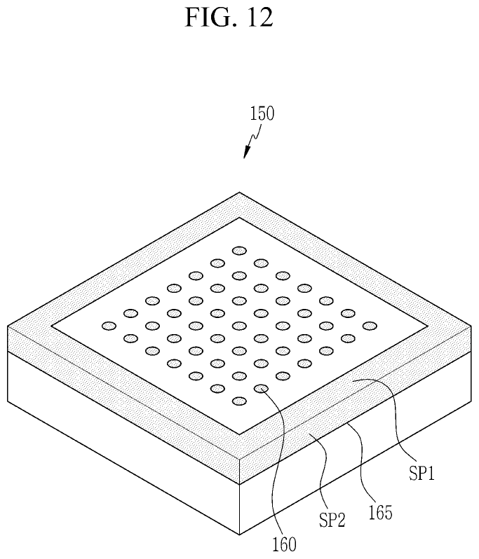

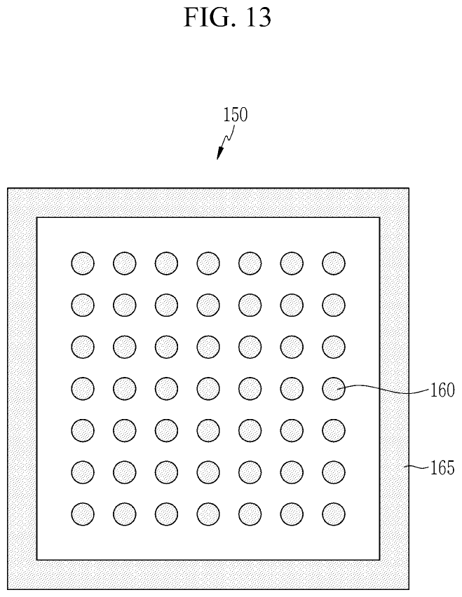

Cross-sectional shapes of the package pad 160 and 165 shown in FIGS. 8 and 9 may also be applied to the semiconductor package 150 according to the embodiments of FIGS. 10 and 11, and semiconductor package 150 according to the embodiments of FIGS. 12 and 13, described later.

FIG. 10 is a schematic perspective view of the semiconductor package 150 according to various embodiments. FIG. 11 is a schematic top view of the semiconductor package 150 according to various embodiments. In FIGS. 10 and 11, the package pads 160 and 165 of the semiconductor package 150 are shown, and other components are omitted. The semiconductor package 150 of FIGS. 10 and 11 may be the semiconductor package 150 included in the semiconductor device 100 of FIGS. 1 to 5. FIG. 10 is a perspective view of a surface of the semiconductor package 150 facing the board 110 when viewed from above. FIG. 11 is a top view of a surface of the semiconductor package 150 of FIG. 10 facing the board 110 when viewed from above. A surface of the semiconductor package 150 facing the board 110 may be a surface of the package substrate 170. The semiconductor package 150 of FIGS. 10 and 11 may be in a state before the solder ball 140 is mounted.

Referring to FIGS. 10 and 11, a surface of the semiconductor package 150 facing the board 110 may include the package center pad 160 and the package edge pad 165.

In various embodiments, the package center pads 160 are positioned in the center of the semiconductor package 150, and may be arranged in an array or lattice shape, for example. The solder balls 140 may be respectively mounted on each of the plurality of package center pads 160. The number of the plurality of package center pads 160 is not limited to the number shown in FIGS. 10 and 11.

In various embodiments, the package edge pads 165 may be positioned along an edge portion of the semiconductor package 150, and may surround the package center pad 160, where the package edge pad 165 may be located on each of the opposite sides of the semiconductor package 150. The package edge pads 165 may cover at least a portion of the surface of the semiconductor package 150 facing the board 110 and a side surface extending therefrom. The package edge pads 165 may have the surface SP1 facing the board 110 and the side surface SP2 extending from the surface SP1 facing the board 110.

In various embodiments, the plurality of package edge pads 165 may be spaced apart from each other along the edge of the semiconductor package 150. The number of the plurality of package edge pads 165 is not limited to the number shown in FIGS. 10 and 11.

In various embodiments, the plurality of package edge pads 165 may have a shape in which a semicircle is coupled to one side of a quadrangle on a plane. For example, a planar shape of the plurality of package edge pads 165 may include a semicircular shape convex toward the center of the semiconductor package 150. The reliability of the solder may be improved if the surface being bonded is a curved surface.

Therefore, as the shape of the package edge pad 165, which is a surface bonded to the board 110, includes a semicircular shape, the reliability after the semiconductor package 150 is mounted on the board 110 can be improved.

FIG. 12 is a schematic perspective view of the semiconductor package 150 according to embodiments. FIG. 13 is a schematic top plan view of the semiconductor package 150 according to various embodiments. In FIGS. 12 and 13, the package pad 160 and 165 of the semiconductor package 150 are shown, and other components are omitted. The semiconductor package 150 of FIGS. 12 and 13 may be the semiconductor package 150 included in the semiconductor device 100 of FIGS. 1 to 5. FIG. 12 is a perspective view of a surface of the semiconductor package 150 facing the board 110 when viewed from above. FIG. 13 is a top view of a surface of the semiconductor package 150 of FIG. 12 facing the board 110 when viewed from above. A surface of the semiconductor package 150 facing the board 110 may be a surface of the package substrate 170. The semiconductor package 150 of FIGS. 12 and 13 may be in a state before the solder ball 140 is mounted.

Referring to FIGS. 12 and 13, a surface of the semiconductor package 150 facing the board 110 may include the package center pads 160 and a single package edge pad 165, where the single package edge pad 165 can extend around the outer edge of the semiconductor package 150.

In various embodiments, the package center pads 160 are positioned in the center of the semiconductor package 150, and may be arranged in a lattice shape, for example. The solder balls 140 may be respectively mounted on each of the plurality of package center pads 160. The number of the plurality of package center pads 160 is not limited to the number shown in FIGS. 12 and 13.

In various embodiments, the package edge pad 165 may be positioned at an edge portion of the semiconductor package 150, and may surround the package center pads 160. The package edge pad 165 may cover at least a portion of the surface of the semiconductor package 150 facing the board 110 and a side surface extending therefrom. The package edge pad 165 may have the surface SP1 facing the board 110 and the side surface SP2 extending from the surface SP1 facing the board 110.

In various embodiments, the single package edge pad 165 may extend along the entire edge of the semiconductor package 150, such that the process of forming the package edge pad 165 may be simplified.

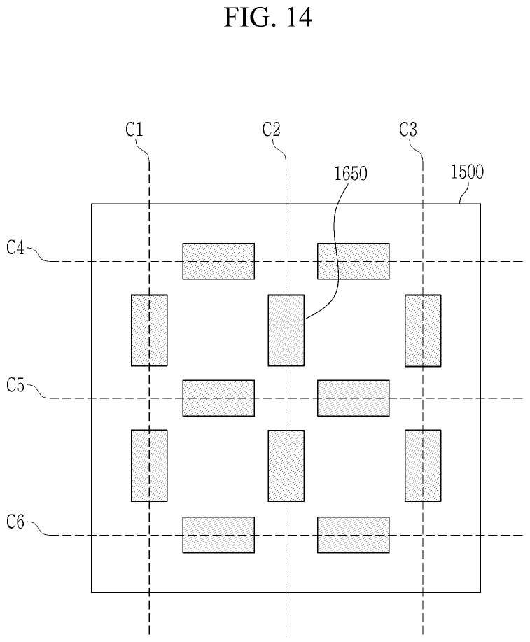

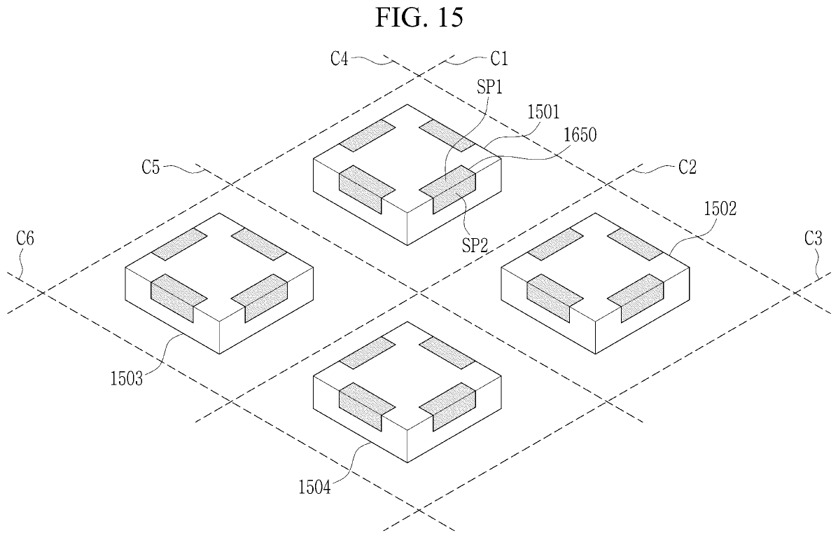

Hereinafter, the shape of a package edge pad 1650 formed by singulation, according to various embodiments, will be described with reference to FIGS. 14 and 15.

FIG. 14 is a schematic top plan view of a package substrate 1500 on which a plurality of semiconductor chips are packaged before singulation. FIG. 15 is a schematic perspective view illustrating a plurality of semiconductor packages 1501, 1502, 1503, and 1504 after singulation. For convenience, the package edge pads 1650 are shown, and other components (e.g., the package center pads) are omitted.

Referring to FIG. 14, a plurality of package edge pads 1650 may be formed on a surface of the package substrate 1500. The plurality of package edge pads 1650 may be disposed to surround a plurality of package regions in which semiconductor chips are packaged. Although not shown, a package center pad may be positioned inside a region surrounded by the plurality of package edge pads 1650. A solder ball may be mounted on a package center pad.

After packaging of the plurality of semiconductor chips is completed on the package substrate 1500, a singulation process (e.g., cutting process) may be performed along lines C1, C2, C3, C4, C5, and C6.

Referring to FIG. 15, the plurality of semiconductor packages 1501, 1502, 1503, and 1504 may be separated by singulation. One package edge pad 1650 on a plane may be divided into two by singulation, and the divided package edge pads 1650 may be positioned at the edge portion of the semiconductor package 1501, 1502, 1503, or 1504, respectively.

By singulation, the package edge pad 1650 may be formed to cover a side surface extending from a surface (a plane shown in FIG. 14) of the semiconductor package 1501. The package edge pad 1650 may include the surface SP1 facing the board in a reflow process and the side surface SP2 extending therefrom. The side surface SP2 of the package edge pad 1650 may be formed on cross-sections cut along lines C1, C2, C3, C4, C5, and C6 by the singulation process.

While the embodiments of the present disclosure have been described in detail, it is to be understood that the disclosure is not limited to the disclosed embodiments, but on the contrary, is intended to cover various modifications and equivalent arrangements included within the spirit and scope of the appended claims.

What is claimed is:

1. A semiconductor device, comprising:
a semiconductor package;
a package center pad positioned at the center of the semiconductor package;
a package edge pad positioned on an edge portion of the semiconductor package, wherein the package edge pad covers at least a portion of a side surface of the semiconductor package; and
a solder ball positioned on the package center pad.

2. The semiconductor device of claim 1, wherein:
a plurality of package edge pads are spaced apart from each other along an edge of the semiconductor package.

3. The semiconductor device of claim 2, wherein:
the plurality of package edge pads have a shape in which a semicircle is coupled to one side of a quadrangle or a quadrangle in a plane view.

4. The semiconductor device of claim 1, wherein:
the package edge pad extends along the edge of the semiconductor package.

5. The semiconductor device of claim 1, wherein:
a thickness of the package edge pad on the side surface of the semiconductor package is greater than or equal to about 10% and less than 100% of a thickness of the semiconductor package.

6. The semiconductor device of claim 1, wherein:
a length of the package edge pad is greater than or equal to about 100% and less than about 300% of a length of the package center pad.

7. The semiconductor device of claim 1, wherein:
a plurality of package center pads is arranged in a lattice shape, and the package edge pad surrounds the package center pad.

8. A semiconductor device, comprising:
a semiconductor package;
a package pad positioned on a surface of the semiconductor package; and
a solder ball positioned on the package pad, wherein the package pad comprises:
a package center pad positioned in the center of the semiconductor package; and
a package edge pad positioned on an edge portion of the semiconductor package, wherein
the package edge pad is thicker than the package center pad.

9. The semiconductor device of claim 8, wherein:
the semiconductor device further comprises:
a board facing the semiconductor package;
a board pad positioned on a surface of the board; and
a paste positioned on the board pad,
wherein the board pad comprises:
a board center pad facing the package center pad; and
a board edge pad facing the package edge pad, and wherein
the solder ball is positioned between the package center pad and the paste.

10. The semiconductor device of claim 9, wherein:
a height of the paste positioned on the board edge pad is greater than or equal to about 100% and less than about 200% of a height of the paste positioned on the board center pad.

11. The semiconductor device of claim 9, wherein:
a length of the board edge pad is greater than or equal to about 120% and less than about 200% of a length of the package edge pad.

12. The semiconductor device of claim 9, wherein:
a length of a paste positioned on the board edge pad is greater than or equal to about 70% and less than about 130% of the length of the board edge pad.

13. The semiconductor device of claim 8, wherein:
the package edge pad has a quadrangle shape on a vertical cross-section of the semiconductor package.

14. The semiconductor device of claim 8, wherein:
the package edge pad has an L-shape on a vertical cross-section of the semiconductor package.

15. A semiconductor device, comprising:
a semiconductor package;
a package pad on a surface of the semiconductor package;
a board facing the semiconductor package;
a board pad on a surface of the board;
a paste on the board pad; and
a solder ball between the package pad and the paste,
wherein the package pad comprises:
a package center pad positioned in the center of the semiconductor package; and
a package edge pad positioned on an edge portion of the semiconductor package, and wherein
the board pad comprises:
a board center pad facing the package center pad; and
a board edge pad facing the package edge pad, wherein
the solder ball is positioned between the package center pad and the board center pad, and
a surface of the package edge pad faces the board and a side surface extending from the surface are covered with the paste.

16. The semiconductor device of claim 15, wherein:
reflow peak temperature of the paste is greater than or equal to about 170° C. and less than about 200° C.

17. The semiconductor device of claim 15, wherein:
the package edge pad is electrically floating.

18. The semiconductor device of claim 15, wherein:
the solder ball is a SAC (Sn, Ag, and Cu) based solder ball.

19. The semiconductor device of claim 15, wherein:
at least a portion of a surface of the package center pad facing the board is covered by the solder ball, and
at least a portion of the solder ball is covered by the paste.

20. The semiconductor device of claim 15, wherein:
a plurality of board center pads is aligned with and arranged in the same pattern as a plurality of package center pads.
